(19) United States
(12) Patent Application Publication
(10) Pub. No.: US 2024/0019744 A1
(43) Pub. Date: Jan. 18, 2024

(54) DISPLAY PANEL AND MANUFACTURING METHOD THEREOF

(71) Applicant: Guangzhou China Star Optoelectronics Semiconductor Display Technology Co., Ltd., Guangzhou, Guangdong (CN)

(72) Inventor: Wei WU, Guangzhou, Guangdong (CN)

(21) Appl. No.: 17/796,658

(22) PCT Filed: Jul. 28, 2022
(86) PCT No.: PCT/CN2022/108440

§ 371 Date: Jul. 31, 2022

(30) Foreign Application Priority Data
Jul. 13, 2022 (CN) 202210828167.1

(51) Int. Cl. G02F 1/1362

(52) U.S. Cl. CPC G02F 1/136295; G02F 1/13625

(57) ABSTRACT

A display panel and a manufacturing method thereof are provided. The display panel at least includes a metal layer, a pixel electrode arranged on a same layer as the metal layer, a protective layer covering the metal layer and the pixel electrode, and a common electrode disposed on the protective layer. A thickness of the protective layer on the metal layer is greater than a thickness of the protective layer on the pixel electrode.

### FIELD OF DISCLOSURE

The present disclosure relates to the field of display technologies, and in particular, to a display panel and a manufacturing method thereof.

### BACKGROUND

With the depletion of fossil energy and a trend of global warming, people's requirements for energy saving are getting higher and higher. The same is true for display products, especially mobile display devices, which have higher requirements for low power consumption.

In a common FFS LCD display panel, a thickness of a protective layer will affect both a turn-on voltage of the liquid crystal display and a capacitance between a metal layer and a common electrode. The larger the thickness of the protective layer, the higher the turn-on voltage, which increases a power consumption of the display. While the thickness of the protective layer is reduced, the parasitic capacitance between the metal layer and the common electrode increases, which also increases the power consumption of the display.

### SUMMARY OF DISCLOSURE

A purpose of the present application is to provide a display panel and a manufacturing method hereof, which aim to reduce a turn-on voltage of liquid crystal and a parasitic capacitance between a metal layer and a common electrode, so as to reduce a power consumption of the display panel.

In one aspect, the present disclosure provides a display panel, the display panel at least includes:
a metal layer;
a pixel electrode arranged at a same layer as the metal layer;
a protective layer covering the metal layer and pixel electrode; and
a common electrode disposed on the protective layer.

A thickness of the protective layer on the metal layer is greater than a thickness of the protective layer on the pixel electrode.

In some embodiments, the protective layer includes:
a first protective layer disposed on the metal layer; and
a second protective layer covering the first protective layer and the pixel electrode.

A thickness of the second protective layer on the first protective layer is equal to a thickness of the second protective layer on the pixel electrode.

In some embodiments, the metal layer includes a source, a drain, and a data line.

In some embodiments, the metal layer is overlapped on an edge of the pixel electrode, or the pixel electrode is overlapped on an edge of the metal layer.

In some embodiments, the display panel further includes:
a substrate;
a gate disposed on the substrate; and
a gate insulating layer disposed on the substrate and covering the gate.

The metal layer and the pixel electrode are disposed on the gate insulating layer.

On the other hand, the present disclosure provides a manufacturing method of a display panel, the manufacturing method of the display panel at least includes:
forming a metal layer;
forming a pixel electrode arranged on a same layer as the metal layer;
forming a protective layer covering the metal layer and the pixel electrode; and
forming a common electrode disposed on the protective layer.

A thickness of the protective layer on the metal layer is greater than a thickness of the protective layer on the pixel electrode.

In some embodiments, the step of forming the protective layer covering the metal layer and the pixel electrode includes:
depositing the protective layer on the metal layer and the pixel electrode; and
removing a portion of the protective layer on the pixel electrode by using a mask, so that the thickness of the protective layer on the metal layer is greater than the thickness of the protective layer on the pixel electrode.

In some embodiments, the metal layer is formed on the gate insulating layer, and the step of forming the protective layer covering the metal layer and the pixel electrode includes:
depositing a first protective layer on the metal layer and the gate insulating layer;
forming a patterned photoresist on the first protective layer by using a mask;
etching the first protective layer by using the patterned photoresist to form an opening that exposes a portion of the gate insulating layer;
removing the patterned photoresist;
forming the pixel electrode in the opening; and
forming a second protective layer on the first protective layer and the pixel electrode, where a thickness of the second protective layer on the first protective layer is equal to a thickness of the second protective layer on the pixel electrode.

The protective layer includes the first protective layer and the second protective layer.

In some embodiments, the step of forming the pixel electrode in the opening includes:
after the step of etching the first protective layer by using the patterned photoresist to form the opening that exposes the portion of the gate insulating layer, depositing the pixel electrode on the exposed gate insulating layer and the patterned photoresist.

In the step of removing the patterned photoresist, the pixel electrode covering the patterned photoresist is removed to form the pixel electrode in the opening.

In some embodiments, the step of forming the protective layer covering the metal layer and the pixel electrode includes:
depositing the first protective layer on the metal layer and the pixel electrode;
removing the first protective layer on the pixel electrode by using a mask; and
forming a second protective layer on the first protective layer and the pixel electrode.

The protective layer includes the first protective layer and the second protective layer.

The present disclosure provides a display panel and a manufacturing method thereof. The display panel at least includes a metal layer, a pixel electrode arranged on a same layer as the metal layer, a protective layer covering the metal layer and the pixel electrode, and a common electrode disposed on the protective layer. A thickness of the protective layer on the metal layer is greater than a thickness of the protective layer on the pixel electrode. That is, the thickness of the protective layer on the metal layer can be set larger, and the thickness of the protective layer on the pixel electrode can be set relatively small. Therefore, a parasitic capacitance between the metal layer and the common electrode can be reduced, and a turn-on voltage of liquid crystal between the pixel electrode and the common electrode can be reduced, both of which can reduce a power consumption of the display panel.

### BRIEF DESCRIPTION OF DRAWINGS

The technical solutions and other beneficial effects of the present disclosure will be apparent through the detailed description of the specific implementations of the present disclosure with reference to the accompanying drawings.

FIG. 1 is a schematic top view of a display panel of an embodiment of the present disclosure.

FIG. 2 is a schematic cross-sectional view of a display panel taken along line A-A1 in FIG. 1 of an embodiment of the present disclosure.

FIG. 3 is a schematic cross-sectional view of a display panel taken along line B-B1 in FIG. 1 of an embodiment of the present disclosure.

FIG. 4 is a schematic cross-sectional view of a display panel taken along line B-B1 in FIG. 1 of another embodiment of the present disclosure.

FIG. 5 is a flowchart of a manufacturing method of a display panel of an embodiment of the present disclosure.

FIG. 6a to FIG. 6c are schematic structural diagrams of a display panel during a manufacturing process of an embodiment of the present disclosure.

FIG. 7a to FIG. 7f are schematic structural diagrams of a display panel during a manufacturing process of another embodiment of the present disclosure.

FIG. 8a to FIG. 8c are schematic structural diagrams of a display panel during a manufacturing process of another embodiment of the present disclosure.

### DETAILED DESCRIPTION

The technical solutions in the embodiments of the present disclosure will be clearly and completely described below with reference to the accompanying drawings in the embodiments of the present disclosure. Obviously, the described embodiments are only some, but not all, embodiments of the present disclosure. Based on the embodiments in the present disclosure, all other embodiments obtained by those skilled in the art without creative efforts shall fall within the protection scope of the present disclosure.

In the description of the present disclosure, it should be understood that terms such as “first” and “second” are used herein for purposes of description and are not intended to indicate or imply relative importance or significance or to imply the number of indicated technical features. Thus, the feature defined with “first” and “second” may comprise one or more of this feature. In the description of the present disclosure, the term “a plurality of” means two or more than two, unless specified otherwise.

In the present disclosure, unless otherwise explicitly stipulated and restricted, that a first feature is “on” or “under” a second feature may include that the first and second features are in direct contact, or may include that the first and second features are not in direct contact but in contact by using other features therebetween. In addition, that the first feature is “on”, “above”, or “over” the second feature includes that the first feature is right above and on the inclined top of the second feature or merely indicates that a level of the first feature is higher than that of the second feature. That the first feature is “below”, “under”, or “beneath” the second feature includes that the first feature is right below and at the inclined bottom of the second feature or merely indicates that a level of the first feature is lower than that of the second feature.

Many different implementations or examples are provided in the following disclosure to implement different structures of the present disclosure. To simplify the disclosure of the present disclosure, components and settings in particular examples are described below. Certainly, they are merely examples and are not intended to limit the present disclosure. In addition, in the present disclosure, reference numerals and/or reference letters may be repeated in different examples. The repetition is for the purposes of simplification and clearness, and a relationship. Moreover, the present disclosure provides examples of various particular processes and materials, but a person of ordinary skill in the art may be aware of application of another process and/or use of another material.

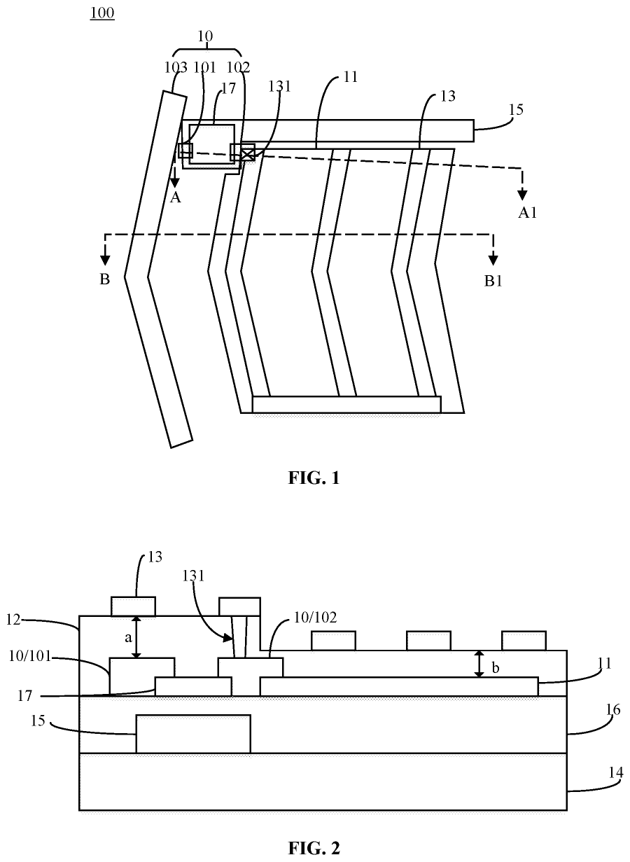

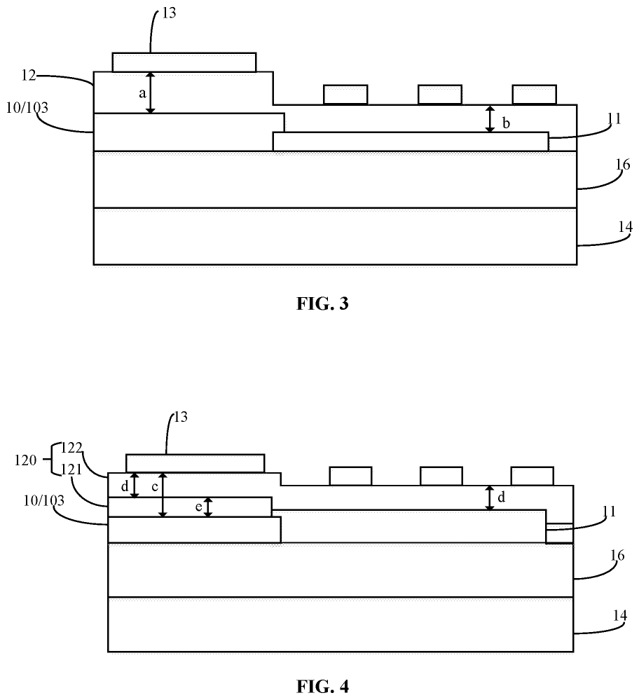

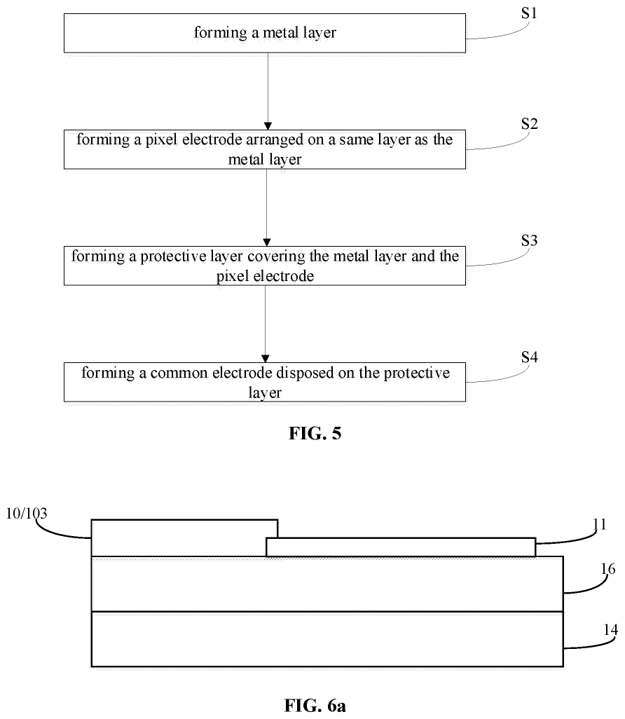

Referring to FIG. 1 FIG. 3, FIG. 1 is a schematic top view of a display panel of an embodiment of the present disclosure, FIG. 2 is a schematic cross-sectional view of a display panel taken along line A-A1 in FIG. 1 of an embodiment of the present disclosure, and FIG. 3 is a schematic cross-sectional view of a display panel taken along line B-B1 in FIG. 1 of an embodiment of the present disclosure. A display panel 100 can be applied to a liquid crystal display (LCD).

The display panel 100 includes at least a metal layer 10, a pixel electrode 11, a protective layer 12, and a common electrode 13. The pixel electrode 11 and the metal layer 10 are arranged on a same layer, the protective layer 12 covers the metal layer 10 and the pixel electrode 11, the common electrode 13 is disposed on the protective layer 12, and the protective layer 12 corresponds to tops of the metal layer 10 and the pixel electrode 11. A thickness a of the protective layer 12 on the metal layer 10 is greater than a thickness b of the protective layer 12 on the pixel electrode 11. The “thickness of the protective layer 12 on the metal layer 10” refers to a thickness of the protective layer 12 between the metal layer 10 and the common electrode 13, and the “thickness of the protective layer 12 on the pixel electrode 11” refers to a thickness of the protective layer 12 between the pixel electrode 11 and the common electrode 13.

Since the thickness a of the protective layer 12 on the metal layer 10 is greater than the thickness b of the protective layer 12 on the pixel electrode 11, the thickness of the protective layer 12 on the metal layer 10 can be set larger, and the thickness of the protective layer 12 on the pixel electrode 11 can be set relatively small. Therefore, a parasitic capacitance between the metal layer 10 and the common electrode 13 can be reduced, and a turn-on voltage of liquid crystal between the pixel electrode 11 and the common electrode 13 can be reduced, both of which can reduce the power consumption of the display panel 100.

As shown in FIG. 1, the pixel electrode 11 may be a planar electrode, and the common electrode 13 may be a strip electrode.

In some embodiments, the metal layer 10 may include a source 101, a drain 102, and a data line 103, and the source 101, the drain 102, and the data line 103 are arranged in a same layer. The source 101 and the drain 102 are shown in FIG. 2, and the data line 103 is shown in FIG. 3.

In some embodiments, the display panel 100 may further include a substrate 14, a gate 15, a gate insulating layer 16, and an active layer 17. The gate 15 is disposed on the substrate 14. The gate insulating layer 16 is disposed on the substrate 14 and covers the gate 15. The active layer 17 is disposed on the gate insulating layer 16 and corresponds to a top of the gate 15. The metal layer 10 and the pixel electrode 11 are also disposed on the gate insulating layer 16. That is, the active layer 17, the metal layer 10, and the pixel electrode 11 are all arranged in a same layer. The protective layer 12 is disposed on the gate insulating layer 16 and covers the active layer 17, the metal layer 10, and the pixel electrode 11.

In one embodiment, the source 101 and the drain 102 of the metal layer 10 are respectively connected to two ends of the active layer 17. The pixel electrode 11 is connected to the drain 102. That is, one end of the drain 102 is connected to the active layer 17, and the other end is connected to the pixel electrode 11. As shown in FIG. 2, the drain 102 is overlapped on an edge of the pixel electrode 11. That is, the other end of drain 102 covers the edge of pixel electrode 11. As shown in FIG. 1 and FIG. 2, the common electrode 13 is connected to the drain 102 through a via hole 131.

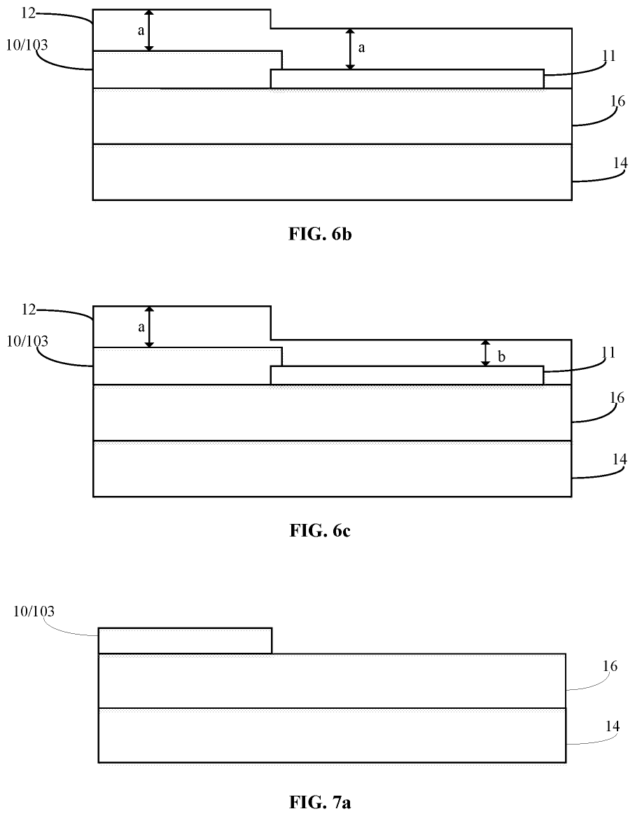

Referring to FIG. 4, FIG. 4 is a schematic cross-sectional view of a display panel taken along line B-B1 in FIG. 1 of another embodiment of the present disclosure. For ease of understanding and brief description, in this embodiment, the same structures in the above-mentioned embodiments use the same reference numerals, and the same structures will not be described in detail.

In this embodiment, the protective layer 120 includes a first protective layer 121 and a second protective layer 122. The first protective layer 121 is disposed on the metal layer 10. The second protective layer 122 covers the first protective layer 121 and the pixel electrode 11. A thickness d of the second protective layer 122 on the first protective layer 121 is equal to a thickness d of the second protective layer 122 on the pixel electrode 11. Since the first protective layer 121 has a certain thickness e on the metal layer 10, the thickness c of the protective layer (including the first protective layer 121 and the second protective layer 122) on the metal layer 10 is equal to the thickness e of the first protective layer 121 plus the thickness d of the second protective layer 122. The thickness d of the protective layer 120 on the pixel electrode 11 is the thickness d of the second protective layer 122. Therefore, the thickness c of the protective layer 120 on the metal layer 10 is greater than the thickness d of the protective layer 120 on the pixel electrode 11.

As shown in FIG. 4, the pixel electrode 11 is overlapped on an edge of the metal layer 10, that is, the pixel electrode 11 covers the edge of the metal layer 10.

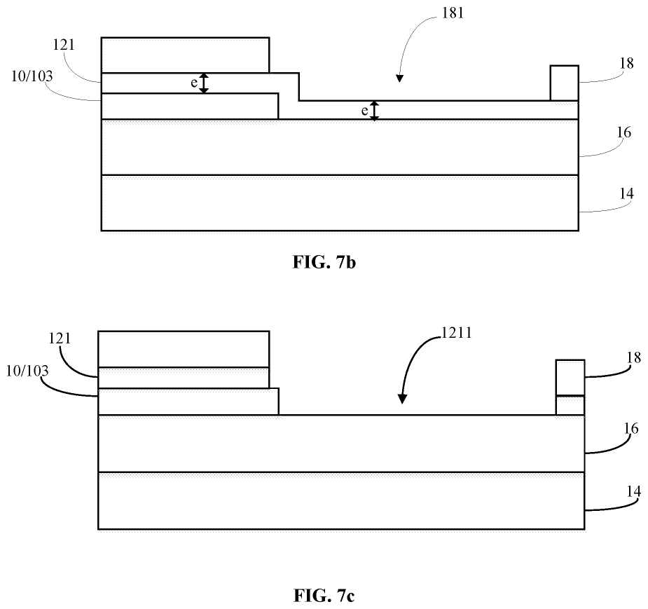

Referring to FIG. 5, FIG. 5 is a flowchart of a manufacturing method of a display panel of an embodiment of the present disclosure. In this embodiment, a manufacturing method of the above-mentioned display panel 100 is taken as an example to describe the manufacturing method. Therefore, reference may be made to FIG. 1 to FIG. 4.

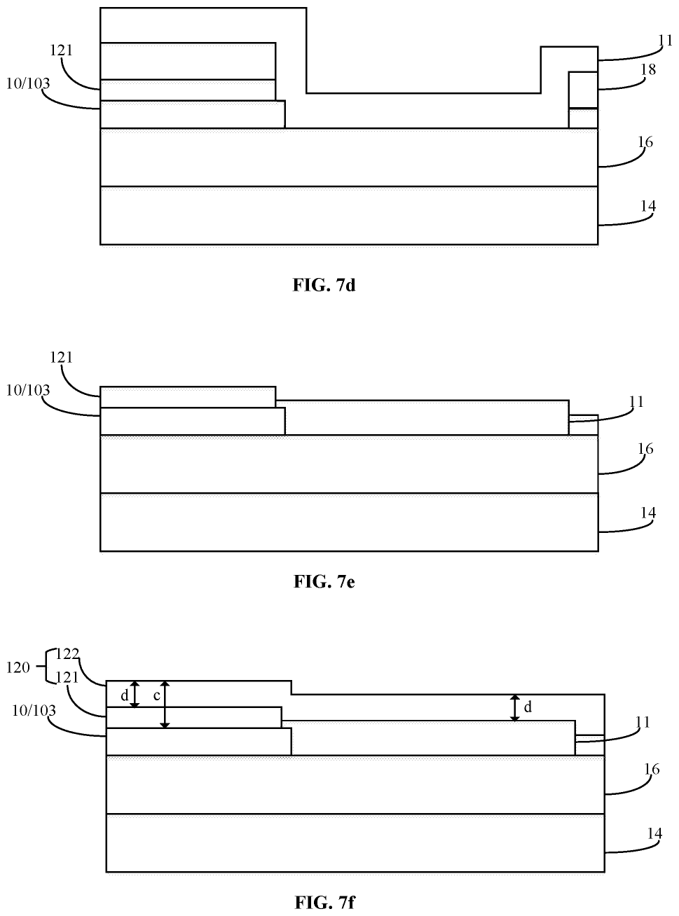

Referring to FIG. 6a to FIG. 6c, FIG. 6a to FIG. 6c are schematic structural diagrams of a display panel during a manufacturing process of an embodiment of the present disclosure, and the manufacturing method includes a following steps S1-S4.

Referring to steps S1-S2 in FIG. 5 and FIG. 6a.

In the step S1: a metal layer 10 is formed.

A substrate 14 is provided first, then a gate insulating layer 16 is formed on the substrate 14, and then the metal layer 10 is formed on the gate insulating layer 16, and various deposition processes can be selected for the formation method. The step of forming the metal layer 10 may include a deposition process and an etching process. That is, an entire surface of the metal layer 10 is deposited first, and then a mask is used to perform an etching process to form a pattern as shown in FIG. 6a.

The substrate 14 may include one or a combination of a glass substrate and a flexible substrate. Material of the gate insulating layer 16 may be SiOx, SiNx, Al2O3/SiNx/SiOx, SiOx/SiNx/SiOx, and the like. Material of the metal layer 10 can be Mo, Mo/Al, Mo/Cu, Mo/Cu/IZO, IZO/Cu/IZO, Mo/Cu/ITO, Ni/Cu/Ni, MoTiNi/Cu/MoTiNi, NiCr/Cu/NiCr, or CuNb, etc.

The metal layer 10 includes a source, a drain, and a data line 103, and the metal layer 10 in FIG. 6a to FIG. 6c shows the data line 103.

In the step S2: a pixel electrode 11 arranged in a same layer as the metal layer 10 is formed.

As shown in FIG. 6a, the metal layer 10 is overlapped on an edge of the pixel electrode 11. Therefore, the step S2 can be performed before the step S1. That is, the pixel electrode 11 is formed first and then the metal layer 10 is formed. In some embodiments, the metal layer 10 may be formed first, and then the pixel electrode 11 is formed. That is, the step S2 is performed after the step S1, and the pixel electrode 11 is overlapped on an edge of the metal layer 10.

The step of forming the pixel electrode 11 may also include a deposition process and an etching process. That is, an entire surface of the pixel electrode 11 is deposited first, and then a mask is used to pattern the pixel electrode 11 to obtain a pattern shown in FIG. 6a. Material of the pixel electrode 11 can be a transparent conductive material, such as indium tin oxide.

Referring to a step S3 in FIG. 5 and FIG. 6b to FIG. 6c.

In the step S3, a protective layer 12 covering the metal layer 10 and the pixel electrode 11 is formed.

In this embodiment, the step S3 may include: 1) as shown in FIG. 6b, a protective layer 12 is deposited on the metal layer 10 and the pixel electrode 11; 2) as shown in FIG. 6c, a portion of the first protective layer 12 on the pixel electrode 11 is removed by using a mask, such that a thickness a of the protective layer 12 on the metal layer 10 is greater than a thickness b of the protective layer 12 on the pixel electrode 11. Material of the protective layer 12 can be SiOx, SiNx, Al2O3/SiNx/SiOx, SiOx/SiNx/SiOx, and the like.

It can be understood that, after the protective layer 12 is deposited, the thickness of the protective layer 12 on the metal layer 10 and the thickness of the protective layer 12 on the pixel electrode 11 are the same (both are a). After removing the portion of the protective layer 12 on the pixel electrode 11, the thickness of the protective layer 12 on the pixel electrode 11 is reduced. Therefore, the final thickness a of the protective layer 12 on the metal layer 10 is greater than the thickness b of the protective layer 12 on the pixel electrode 11.

In one embodiment, in the process of etching the protective layer 12 with one mask, not only the portion of the protective layer 12 on the pixel electrode 11 should be removed, but also the protective layer 12 in other areas (not shown in the figure) should be completely removed. Therefore, a half tone mask (HTM) can be used to etch the protective layer 12, so as to completely remove the protective layer 12 in other areas, and only remove the portion of the protective layer 12 on the pixel electrode 11, that is, different areas have different etching thicknesses.

Referring to a step S4 in FIG. 5 and FIG. 3.

In the step S4: a common electrode 13 on the protective layer 12 is formed.

Specifically, the common electrode 13 is deposited on the protective layer 12 and patterned with a mask to form a pattern shown in FIG. 3. Material of the common electrode 13 can also be a transparent conductive material, such as indium tin oxide.

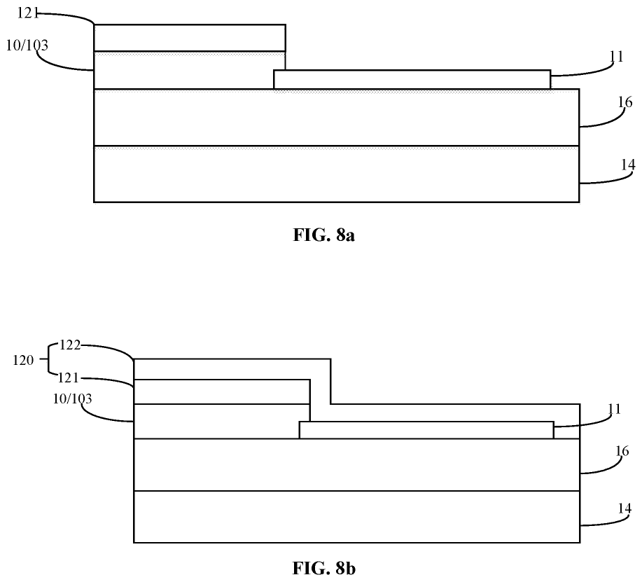

Referring to FIG. 5, FIG. 7a to FIG. 7f, and FIG. 4, FIG. 7a to FIG. 7f are schematic structural diagrams of a display panel during a manufacturing process of another embodiment of the present disclosure.

In this embodiment, the step S1 is first performed, as shown in FIG. 7 a, the metal layer 10 is formed on the gate insulating layer 16. Then, the step S3 is performed, as shown in FIG. 7b to FIG. 7f, the protective layer 120 covering the metal layer 10 and the pixel electrode 11 is formed. The protective layer 120 includes the first protective layer 121 and the second protective layer 122. The step S2 is performed in the process of performing the step S3, as shown in FIG. 7d to FIG. 7e, the pixel electrode 11 arranged in the same layer as the metal layer 10 is formed. Finally, the step S4 is performed, as shown in FIG. 4, the common electrode 13 disposed on the protective layer 120 is formed.

The step S3 specifically includes the following steps.
1) As shown in FIG. 7b, the first protective layer 121 is deposited on the metal layer 10 and the gate insulating layer 16. In the same deposition process, the thickness e of the first protective layer 121 on the metal layer 10 is equal to the thickness e on the gate insulating layer 16.
2) As shown in FIG. 7b, a patterned photoresist 18 is formed on the first protective layer 121 using a mask. Specifically, a photoresist is first coated on the first protective layer 121, and then the photoresist is subjected to a photolithography process (exposure and development) using the mask to form a predetermined shape (i.e., the patterned photoresist 18). The predetermined shape depends on a position of the pixel electrode 11 to be formed subsequently. The patterned photoresist 18 has a preset opening 181. The pixel electrode 11 formed subsequently corresponds to the preset opening 181.
3) As shown in FIG. 7c, using the patterned photoresist 18, the first protective layer 121 is etched to form an opening 1211 exposing a portion of the gate insulating layer 16. The opening 1211 corresponds to the above-mentioned preset opening 181.
4) As shown in FIG. 7d, the pixel electrode 11 is deposited on the exposed gate insulating layer 16 and patterned photoresist 18.
5) As shown in FIG. 7e, the patterned photoresist 18 is removed, and the pixel electrode 11 covering the patterned photoresist 18 is removed to form a pixel electrode 11 in the opening 1211. Therefore, both the pixel electrode 11 and the metal layer 10 are formed on the gate insulating layer 16. The formation of the pixel electrode 11 does not require an additional mask, but the pixel electrode 11 shown in FIG. 7e is formed by stripping the patterned photoresist 18 formed by the mask in the step 2.
6) As shown in FIG. 7f, the second protective layer 122 is formed on the first protective layer 121 and the pixel electrode 11, and the thickness d of the second protective layer 122 on the first protective layer 121 is equal to the thickness d on the pixel electrode 11. Therefore, the thickness c of the protective layer 120 (the first protective layer 121 plus the second protective layer 122) on the metal layer 10 is greater than the thickness d of the protective layer 120 (the second protective layer 122) on the pixel electrode 11. The method of forming the second protective layer 122 may include a deposition process and an etching process. That is, a whole surface of the second protective layer 122 is first deposited, and then the second protective layer 122 in other areas (not shown in the figure) is etched to form the second protective layer 122 as shown in FIG. 7f.

In the manufacturing process of the display panel of this embodiment, the pixel electrode 11 is formed after the first protective layer 121, and the second protective layer 122 is formed after the pixel electrode 11. Although one mask is used for the formation of the first protective layer 121, no additional mask is used for the formation of the pixel electrode 11. The pixel electrode 11 is patterned by stripping the patterned photoresist 18 of the mask forming the first protective layer 121. Therefore, the overall manufacturing process does not increase the number of masks.

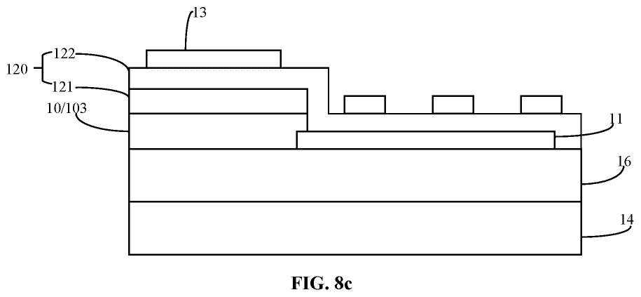

Referring to FIG. 5 and FIG. 8a to FIG. 8c, FIG. 8a to FIG. 8c are schematic structural diagrams of a display panel during a manufacturing process of another embodiment of the present disclosure. For ease of understanding and brief description, in this embodiment, the same structures in the above-mentioned embodiments use the same reference numerals, and the same structures will not be described in detail.

As shown in FIG. 8a, in this embodiment, the pixel electrode 11 can be formed first, and then the metal layer 10 can be formed, that is, the step S2 is performed first and then the step S1 is performed. The metal layer 10 is overlapped on the edge of the pixel electrode 11. The specific processes of the step S1 and the step S2 may include a deposition process and a patterning process, respectively.

Then, the step S3 is performed, specifically, the first protective layer 121 is deposited on the metal layer 10 and the pixel electrode 11, the first protective layer 121 on the pixel electrode 11 is removed by patterning with a mask, and the photoresist is stripped after patterning. Next, as shown in FIG. 8b, the second protective layer 122 is formed on the first protective layer 121 and the pixel electrode 11. Therefore, the first protective layer 121 and the second protective layer 122 constitute the protective layer 120. The thickness of the protective layer 120 (including the first protective layer 121 and the second protective layer 122) on the metal layer 10 is greater than the thickness of the protective layer 120 (including the second protective layer 122) on the electrode pixel 11.

As shown in FIG. 8c, the step S4 is finally performed to form the common electrode 13 on the second protective layer 122, and the step S4 may specifically include a deposition process and a patterning process.

In the manufacturing method of the display panel of the embodiment of the present disclosure, if there is only one protective layer 12, the pixel electrode 11 can be formed before the protective layer 12 (FIG. 6a to FIG. 6c). If the protective layer 120 includes the first protective layer 121 and the second protective layer 122, the pixel electrode 11 may be formed after the first protective layer 121 (FIG. 7a to FIG. 71). If the protective layer 120 includes the first protective layer 121 and the second protective layer 122, the pixel electrode 11 may also be formed before the first protective layer 121 (FIG. 8a to FIG. 8c). Since the thickness of the protective layer 12/120 on the metal layer 10 is greater than the thickness of the protective layer 12/120 on the pixel electrode 11, the thickness of the protective layer 12/120 can take into account the requirement of a parasitic capacitance between the metal layer 10 and the common electrode 13, and the requirement of a turn-on voltage of the liquid crystal between the pixel electrode 11 and the common electrode 13, which can reduce a power consumption of the display panel.

The descriptions of the above embodiments are only used to help understand the technical solutions and core ideas of the present disclosure. Those skilled in the art should understand that they can still make modifications to the technical solutions described in the foregoing embodiments, or perform equivalent replacements to some of the technical features. These modifications or replacements do not make the essence of the corresponding technical solutions deviate from the scope of the technical solutions of the various embodiments of the present disclosure.

What is claimed is:

1. A display panel, comprising:
a metal layer;
a pixel electrode arranged at a same layer as the metal layer;
a protective layer covering the metal layer and pixel electrode; and
a common electrode disposed on the protective layer;
wherein a thickness of the protective layer on the metal layer is greater than a thickness of the protective layer on the pixel electrode.

2. The display panel according to claim 1, wherein the protective layer comprises:
a first protective layer disposed on the metal layer; and
a second protective layer covering the first protective layer and the pixel electrode;
wherein a thickness of the second protective layer on the first protective layer is equal to a thickness of the second protective layer on the pixel electrode.

3. The display panel according to claim 1, wherein the metal layer comprises a source, a drain, and a data line.

4. The display panel according to claim 1, wherein the metal layer is overlapped on an edge of the pixel electrode, or the pixel electrode is overlapped on an edge of the metal layer.

5. The display panel according to claim 1, wherein the display panel further comprises:
a substrate;
a gate disposed on the substrate; and
a gate insulating layer disposed on the substrate and covering the gate;
wherein the metal layer and the pixel electrode are disposed on the gate insulating layer.

6. The display panel according to claim 3, wherein the source, the drain, and the data line are arranged in a same layer.

7. A manufacturing method of a display panel, comprising:
forming a metal layer;
forming a pixel electrode arranged on a same layer as the metal layer;
forming a protective layer covering the metal layer and the pixel electrode; and
forming a common electrode disposed on the protective layer;
wherein a thickness of the protective layer on the metal layer is greater than a thickness of the protective layer on the pixel electrode.

8. The manufacturing method of the display panel according to claim 7, wherein the step of forming the protective layer covering the metal layer and the pixel electrode comprises:
depositing the protective layer on the metal layer and the pixel electrode; and
removing a portion of the protective layer on the pixel electrode by using a mask, so that the thickness of the protective layer on the metal layer is greater than the thickness of the protective layer on the pixel electrode.

9. The manufacturing method of the display panel according to claim 7, wherein the metal layer is formed on the gate insulating layer, and the step of forming the protective layer covering the metal layer and the pixel electrode comprises:
depositing a first protective layer on the metal layer and the gate insulating layer;
forming a patterned photoresist on the first protective layer by using a mask;
etching the first protective layer by using the patterned photoresist to form an opening that exposes a portion of the gate insulating layer;
removing the patterned photoresist;
forming the pixel electrode in the opening; and
forming a second protective layer on the first protective layer and the pixel electrode, wherein a thickness of the second protective layer on the first protective layer is equal to a thickness of the second protective layer on the pixel electrode; and
wherein the protective layer comprises the first protective layer and the second protective layer.

10. The manufacturing method of the display panel according to claim 9, wherein the step of forming the pixel electrode in the opening comprises:
after the step of etching the first protective layer by using the patterned photoresist to form the opening that exposes the portion of the gate insulating layer, depositing the pixel electrode on the exposed gate insulating layer and the patterned photoresist; and
wherein in the step of removing the patterned photoresist, the pixel electrode covering the patterned photoresist is removed to form the pixel electrode in the opening.

11. The manufacturing method of the display panel according to claim 7, wherein the step of forming the protective layer covering the metal layer and the pixel electrode comprises:
depositing the first protective layer on the metal layer and the pixel electrode;
removing the first protective layer on the pixel electrode by using a mask; and
forming a second protective layer on the first protective layer and the pixel electrode;
wherein the protective layer comprises the first protective layer and the second protective layer.

12. The manufacturing method of the display panel according to claim 7, wherein the metal layer comprises a source, a drain, and a data line.

13. The manufacturing method of the display panel according to claim 12, wherein the source, the drain, and the data lines are arranged in a same layer.

14. The manufacturing method of the display panel according to claim 7, wherein the metal layer is overlapped on an edge of the pixel electrode, or the pixel electrode is overlapped on an edge of the metal layer.

15. The manufacturing method of the display panel according to claim 7, wherein the manufacturing method of the display panel further comprises:
providing a substrate;
forming a gate on the substrate; and
forming a gate insulating layer on the substrate and covering the gate;
wherein the metal layer and the pixel electrode are disposed on the gate insulating layer.
